(19) United States
(12) Patent Application Publication
(10) Pub. No.: US 2011/0008947 A1
(43) Pub. Date: Jan. 13, 2011

(54) APPARATUS AND METHOD FOR PERFORMING MULTIFUNCTION LASER PROCESSES

(75) Inventors: KEVIN LAUGHTON CUNNINGHAM, Mountain View, CA (US); Carl Treadwell, Menlo Park, CA (US); Tzay-Fa Su, San Jose, CA (US); Uday Mahajan, Santa Clara, CA (US); Sarin Sundar Jainnagar Kuppuswamy, Hyderabad (IN)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/817,499

(22) Filed: Jun. 17, 2010

Related U.S. Application Data
(60) Provisional application No. 61/225,105, filed on Jul. 13, 2009.

(51) Int. Cl. H01L 21/78; B23K 26/00

(52) U.S. Cl. 438/463; 219/121.68; 257/E21.599

(57) ABSTRACT

Embodiments of the present invention generally relate to a system used to form solar cell devices using processing modules adapted to perform one or more processes in the formation of the solar cell devices. In one embodiment, the system is adapted to form thin film solar cell devices by accepting a large unprocessed substrate and performing multiple deposition, material removal, cleaning, bonding, testing, and sectioning processes to form one or more complete, functional, and tested solar cell devices in custom sizes and/or shapes that can then be shipped to an end user for installation in a desired location to generate electricity. In one embodiment, the system is adapted to form one or more BIPV panels in custom sizes and/or shapes from a single large substrate for shipment to an end user.

### CROSS-REFERENCE TO RELATED APPLICATIONS

This application claims benefit of U.S. provisional patent application Ser. No. 61/225,105, filed Jul. 13, 2009, which is incorporated herein by reference. This application is related to U.S. application Ser. No. No. 12/430,755, filed Apr. 27, 2009 (Attorney Docket No. APPM/13972) and U.S. application Ser. No. 12/201,840, filed Aug. 29, 2008 (Attorney Docket No. APPM/11141.02), each of which is incorporated by reference herein.

### BACKGROUND OF THE INVENTION

1. Field of the Invention

Embodiments of the present invention generally relate to a production line used to form multiple sized solar cell devices. In particular, embodiments of the invention include incorporating multiple laser processes within a single module within a production line for forming custom sized and shaped solar cell devices.

2. Description of the Related Art

Photovoltaic (PV) devices or solar cells are devices which convert sunlight into direct current (DC) electrical power. Typical thin film type PV devices, or thin film solar cells, have one or more p-i-n junctions. Each p-i-n junction comprises a p-type layer, an intrinsic type layer, and an n-type layer. When the p-i-n junction of the solar cell is exposed to sunlight (consisting of energy from photons), the sunlight is converted to electricity through the PV effect.

Typically, a thin film solar cell includes active regions, or photoelectric conversion units, and a transparent conductive oxide (TCO) film disposed as a front electrode and/or as a back electrode. The photoelectric conversion unit includes a p-type silicon layer, an n-type silicon layer, and an intrinsic type (i-type) silicon layer sandwiched between the p-type and n-type silicon layers. Several types of silicon films including microcrystalline silicon film (μc-Si), amorphous silicon film (a-Si), polycrystalline silicon film (poly-Si), and the like may be utilized to form the p-type, n-type, and/or i-type layers of the photoelectric conversion unit. The backside electrode may contain one or more conductive layers.

There is a need for a low cost method of producing electricity using a low cost solar cell device. Conventional solar cell manufacturing processes are highly labor intensive and have numerous interruptions that can affect the production line throughput, solar cell cost, and device yield. For instance, particular solar cell device sizes and shapes are needed for particular applications. Conventional solar cell lines are either capable of producing only a single sized, rectangular solar cell device or require significant downtime to manually convert the solar cell production line processes to accommodate a different substrate size and/or shape and produce a different sized and/or shaped solar cell device. Additionally, building integrated photovoltaics (BIPV), which are used as windows or skylights in architectural applications, are semi-transparent solar cells requiring additional material removal of the backside electrode. Conventional solar cell lines are either incapable of producing BIPV panels or require significant downtime for adding or reconfiguring process modules to perform the additional operations needed to produce BIPV panels.

Thus, there is a need for a production line that is able to perform all phases of the fabrication process for producing multiple, custom sized and/or shaped solar cell devices from a single large substrate, including BIPV panels.

### SUMMARY OF THE INVENTION

In one embodiment of the present invention, an apparatus for performing multiple laser functions on a substrate having a plurality of layers formed thereon comprises a substrate handling device configured to support and move the substrate, a first laser device configured to remove a portion of at least one of the plurality of layers in a first two dimensional pattern, a second laser device configured to propagate a crack in the substrate along a scribed two dimensional pattern, and a system controller in communication with the substrate handling device, the first laser device, and the second laser device, wherein the system controller is configured to control the positioning and movement of the substrate, the first laser device, and the second laser device.

In another embodiment of the present invention, a method for performing multiple laser functions on a substrate having a plurality of layers formed thereon comprises receiving the substrate onto a substrate handling device, removing a portion of at least one of the plurality of layers in a first two dimensional pattern via a first laser device, propagating a crack in the substrate along a scribed two dimensional pattern via a second laser device, and removing the substrate from the substrate handling device.

In yet another embodiment of the present invention, a system for fabricating solar cell devices comprises a first scribing module configured to scribe one or more first trenches in a front contact layer of a solar cell substrate, one or more cluster tools having at least one chamber configured to deposit at least one silicon-containing layer over the front contact layer, a second scribing module configured to scribe one or more second trenches in the at least one silicon-containing layer, a deposition module configured to deposit a back contact layer over the at least one silicon-containing layer, a third scribing module configured to scribe one or more third trenches in the back contact layer, a multifunction laser module comprising a first laser device and a second laser device, and a system controller in communication with at least the multifunction laser module, wherein the system controller is configured to control the positioning and movement of the substrate, the first laser device, and the second laser device. In one embodiment, the first laser device is configured to remove a portion of at least the back contact layer and the at least one silicon-containing layer in a first two-dimensional pattern. In one embodiment, the second laser device is configured to propagate a crack in the substrate along a scribed two-dimensional pattern.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a process sequence for forming a solar cell device according to one embodiment described herein.

FIG. 2 illustrates a plan view of a solar cell production line according to one embodiment described herein.

FIG. 3A is a side cross-sectional view of a thin film solar cell device according to one embodiment described herein.

FIG. 3B is a side cross-sectional view of a thin film solar cell device according to one embodiment described herein.

FIG. 3C is a plan view of a composite solar cell structure according to one embodiment described herein.

FIG. 3D is a plan view of a composite solar cell structure according to one embodiment described herein.

FIG. 3E is a cross-sectional view of along Section A-A of FIG. 3C.

FIG. 3F is a side cross-sectional view of a thin film solar cell device according to one embodiment described herein.

FIG. 4A is a schematic, plan view of a multifunction laser module according to one embodiment of the present invention.

FIG. 4B is a schematic, cross-sectional view of the multifunction laser module in FIG. 4A.

FIGS. 5A-5C are schematic side views of portions of a laser module illustrating a sequence for sectioning a partially formed solar cell device according to one embodiment of the present invention.

FIG. 6 is a schematic depiction of a laser cutting device for sectioning a composite solar cell structure according to one embodiment of the present invention.

FIGS. 7A-7C schematically illustrate a process for sectioning a composite structure solar cell structure according to one embodiment of the present invention.

For clarity, identical reference numerals have been used, where applicable, to designate identical elements that are common between figures. It is contemplated that features of one embodiment may be incorporated in other embodiments without further recitation.

### DETAILED DESCRIPTION

Embodiments of the present invention generally relate to a system used to form solar cell devices using processing modules adapted to perform one or more processes in the formation of the solar cell devices. In one embodiment, the system is adapted to form thin film solar cell devices by accepting a large unprocessed substrate and performing multiple deposition, material removal, cleaning, bonding, testing, and sectioning processes to form one or more complete, functional, and tested solar cell devices in custom sizes and/or shapes that can then be shipped to an end user for installation in a desired location to generate electricity. In one embodiment, the system is adapted to form one or more BIPV panels in custom sizes and/or shapes from a single large substrate for shipment to an end user.

In one embodiment, the system is capable of accepting a single large unprocessed substrate and producing one or more custom sized and shaped solar cell devices without manually moving or altering any of the system modules. In one embodiment, the system is also capable of producing BIPV panels without manually moving or altering any of the system modules. While the discussion below primarily describes the formation of silicon thin film solar cell devices, this configuration is not intended to limit the scope of the invention since the apparatus and methods disclosed herein can also be used to form, test, and analyze other types of solar cell devices, such as III-V type solar cells, thin film chalcogenide solar cells (e.g., CIGS, CdTe cells), amorphous or nanocrystalline silicon solar cells, photochemical type solar cells (e.g., dye sensitized), crystalline silicon solar cells, organic type solar cells, or other similar solar cell devices.

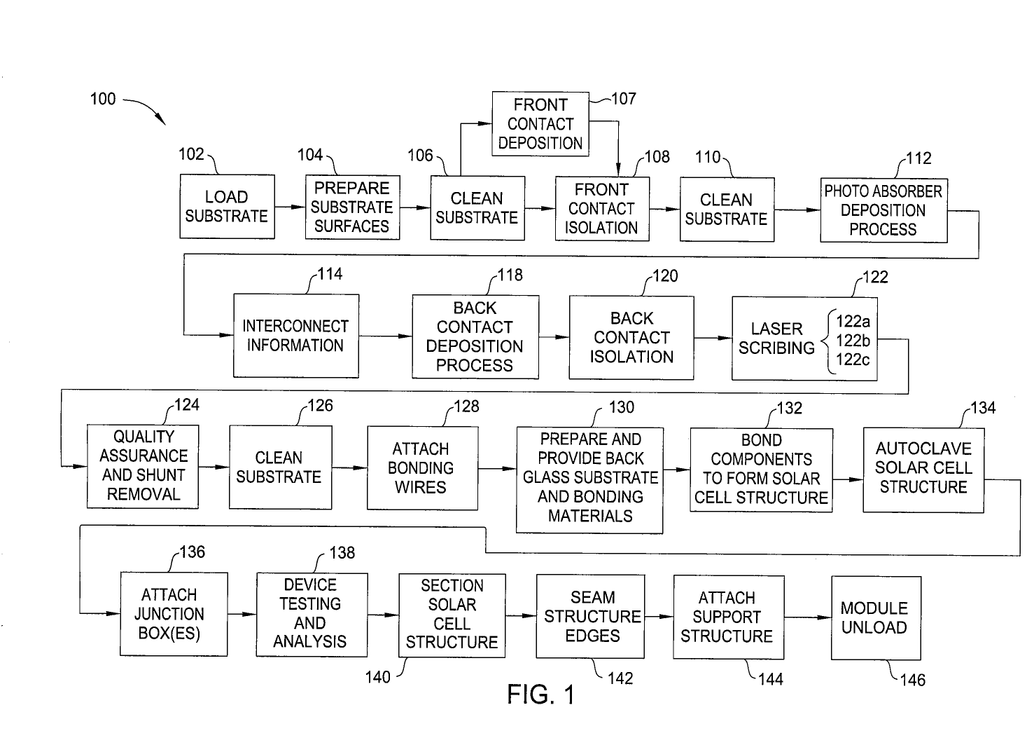

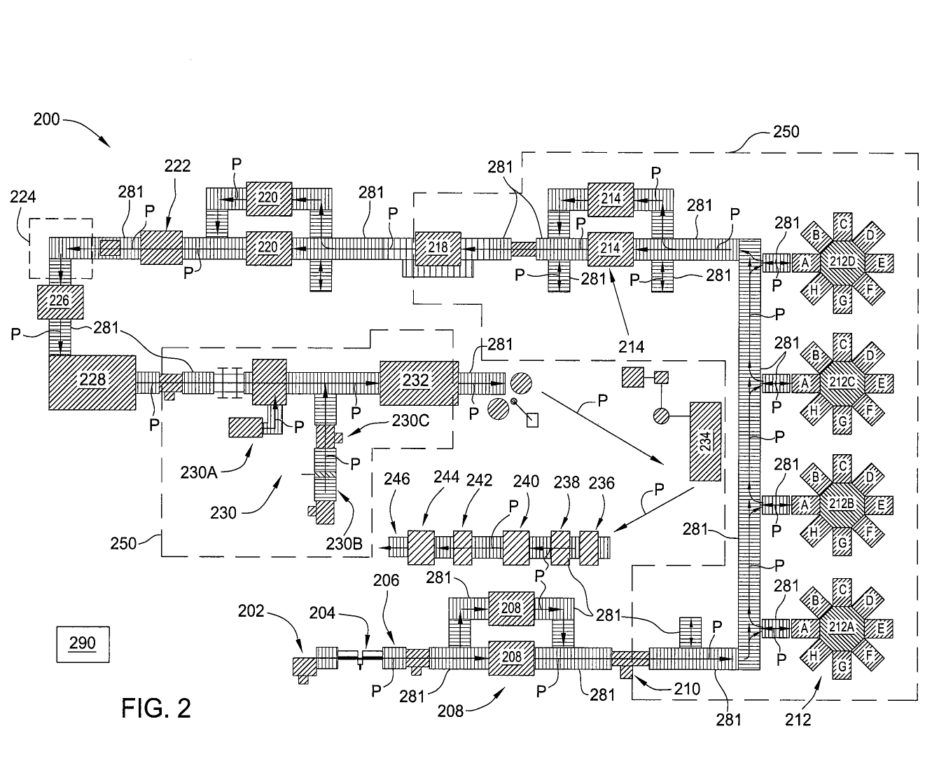

FIG. 1 illustrates one embodiment of a process sequence 100 that includes a plurality of steps (i.e., steps 102-146) that are used to form a solar cell device in a novel solar cell production line 200 described herein. The configuration, number of processing steps, and order of the processing steps in the process sequence 100 is not intended to limit the scope of the invention described herein. FIG. 2 is a plan view of one embodiment of the production line 200, which is intended to illustrate some of the typical processing modules and process flows through the system and other related aspects of the system design, and is thus not intended to limit the scope of the invention described herein.

In general, a system controller 290 may be used to control one or more components found in the solar cell production line 200. The system controller 290 is generally designed to facilitate the control and automation of the overall solar cell production line 200 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and support hardware (e.g., sensors, robots, motors, lamps, etc.), and monitor the processes (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 290 determines which tasks are performable on a substrate. Preferably, the program is software readable by the system controller 290 that includes code to perform tasks relating to monitoring, execution and control of the movement, support, and/or positioning of a substrate along with the various process recipe tasks and various chamber process recipe steps being performed in the solar cell production line 200. In one embodiment, the system controller 290 also contains a plurality of programmable logic controllers (PLC's) that are used to locally control one or more modules in the solar cell production, and a material handling system controller (e.g., PLC or standard computer) that deals with the higher level strategic movement, scheduling and running of the complete solar cell production line.

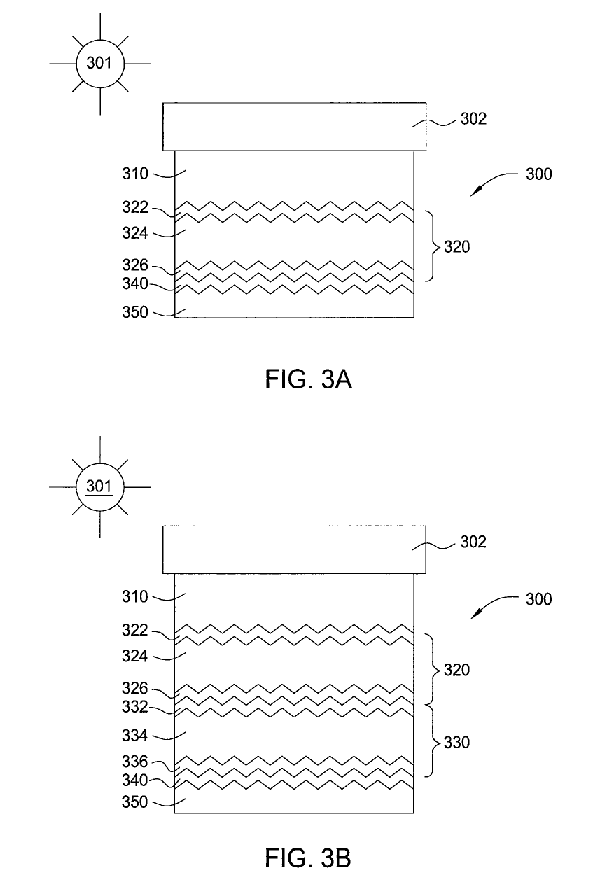

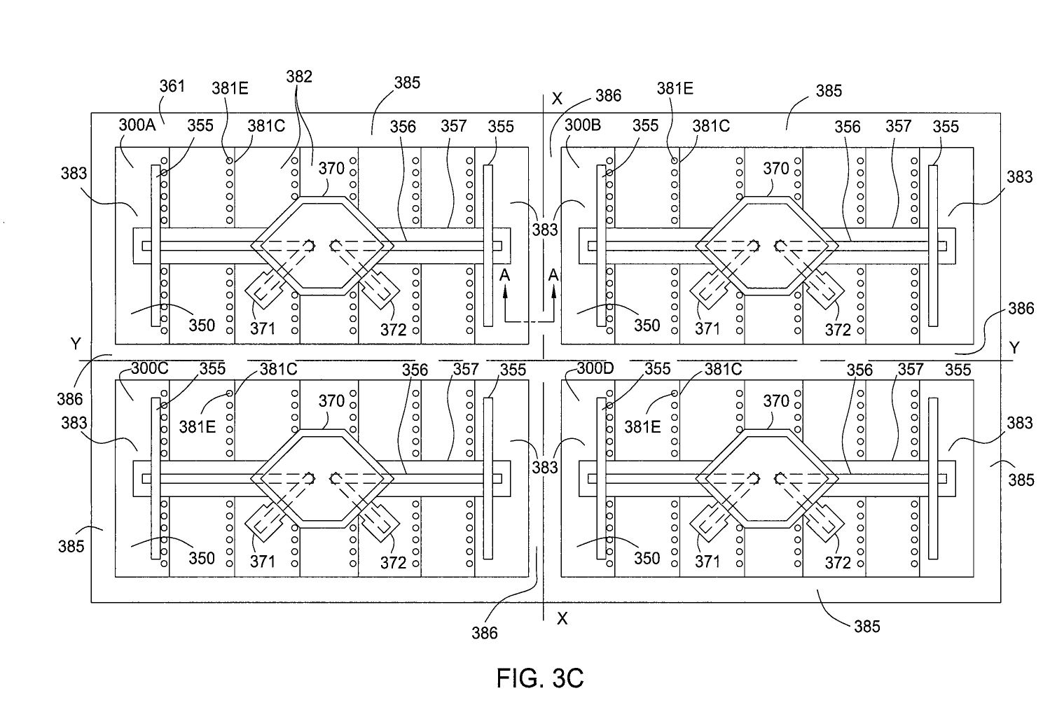

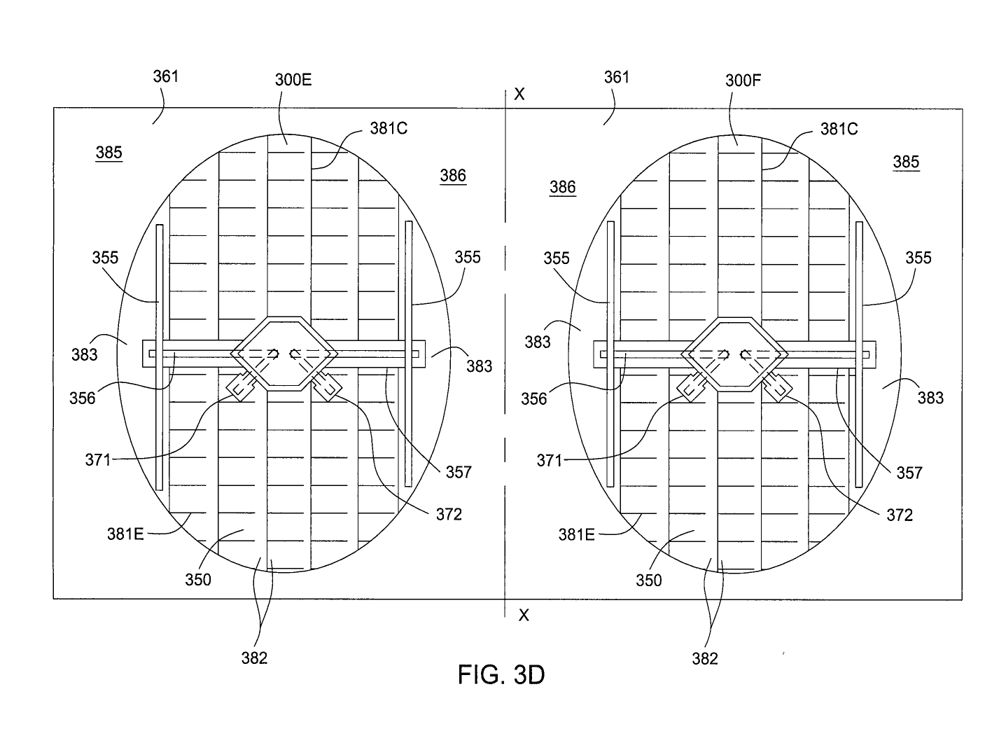

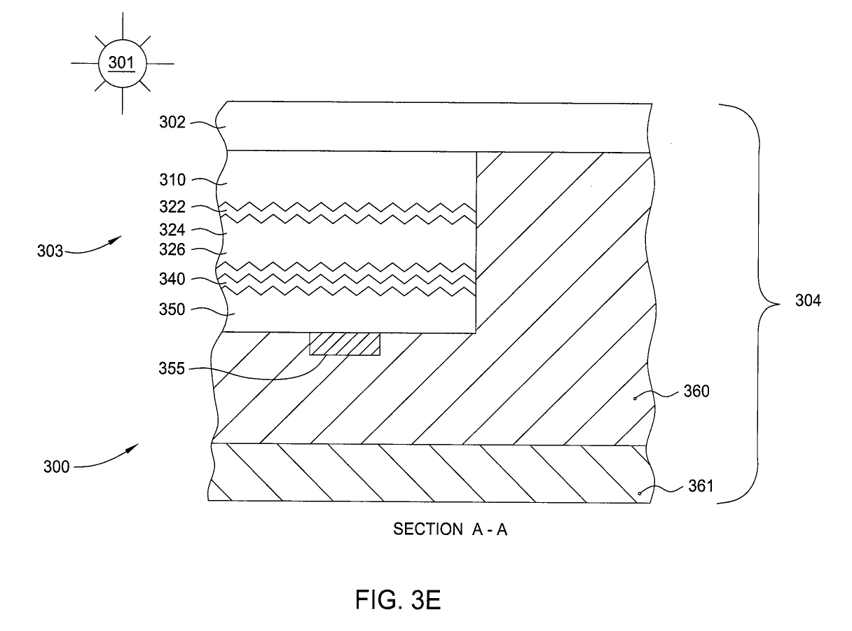

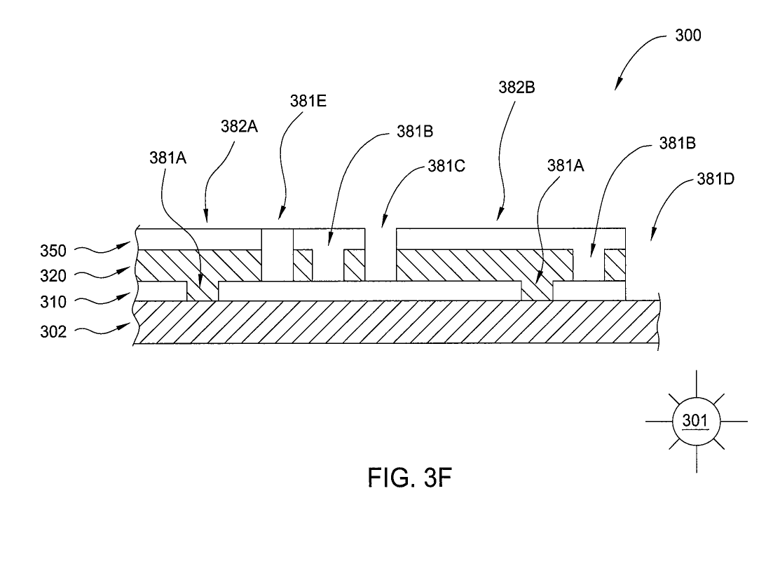

Examples of a solar cell 300 that can be formed using the process sequence(s) illustrated in FIG. 1 and the components illustrated in the solar cell production line 200 are illustrated in FIGS. 3A-3F. FIG. 3A is a simplified schematic diagram of a single junction amorphous or micro-crystalline silicon solar cell 300 that can be formed and analyzed in the system described below. As shown in FIG. 3A, the single junction amorphous or micro-crystalline silicon solar cell 300 is oriented toward a light source or solar radiation 301. The solar cell 300 generally comprises a substrate 302, such as a glass substrate, polymer substrate, metal substrate, or other suitable substrate, with thin films formed thereover. In one embodiment, the substrate 302 is a glass substrate that is about 2200 mm×2600 mm×3 mm in size. The solar cell 300 further comprises a first transparent conducting oxide (TCO) layer 310 (e.g., zinc oxide (ZnO), tin oxide (SnO)) formed over the substrate 302, a first p-i-n junction 320 formed over the first TCO layer 310, a second TCO layer 340 formed over the first p-i-n junction 320, and a back contact layer 350 formed over the second TCO layer 340.

To improve light absorption by enhancing light trapping, the substrate and/or one or more of the thin films formed thereover may be optionally textured by wet, plasma, ion, and/or mechanical processes. For example, in the embodiment shown in FIG. 3A, the first TCO layer 310 is textured, and the subsequent thin films deposited thereover generally follow the topography of the surface below it.

In one configuration, the first p-i-n junction 320 may comprise a p-type amorphous silicon layer 322, an intrinsic type amorphous silicon layer 324 formed over the p-type amorphous silicon layer 322, and an n-type amorphous silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type amorphous silicon layer 326 may be formed to a thickness between about 100 Å and about 500 Å. The back contact layer 350 may include, but is not limited to a material selected from Al, Ag, Ti, Cr, Au, Cu, Pt, alloys thereof, and combinations thereof.

FIG. 3B is a schematic diagram of an embodiment of a solar cell 300, which is a multi-junction solar cell that is oriented toward the light or solar radiation 301. The solar cell 300 comprises a substrate 302, such as a glass substrate, polymer substrate, metal substrate, or other suitable substrate, with thin films formed thereover. The solar cell 300 may further comprise a first transparent conducting oxide (TCO) layer 310 formed over the substrate 302, a first p-i-n junction 320 formed over the first TCO layer 310, a second p-i-n junction 330 formed over the first p-i-n junction 320, a second TCO layer 340 formed over the second p-i-n junction 330, and a back contact layer 350 formed over the second TCO layer 340. In the embodiment shown in FIG. 3B, the first TCO layer 310 is textured, and the subsequent thin films deposited thereover generally follow the topography of the surface below it.

The first p-i-n junction 320 may comprise a p-type amorphous silicon layer 322, an intrinsic type amorphous silicon layer 324 formed over the p-type amorphous silicon layer 322, and an n-type microcrystalline silicon layer 326 formed over the intrinsic type amorphous silicon layer 324. In one example, the p-type amorphous silicon layer 322 may be formed to a thickness between about 60 Å and about 300 Å, the intrinsic type amorphous silicon layer 324 may be formed to a thickness between about 1,500 Å and about 3,500 Å, and the n-type microcrystalline silicon layer 326 may be formed to a thickness between about 100 Å and about 400 Å.

The second p-i-n junction 330 may comprise a p-type microcrystalline silicon layer 332, an intrinsic type microcrystalline silicon layer 334 formed over the p-type microcrystalline silicon layer 332, and an n-type amorphous silicon layer 336 formed over the intrinsic type microcrystalline silicon layer 334. In one example, the p-type microcrystalline silicon layer 332 may be formed to a thickness between about 100 Å and about 400 Å, the intrinsic type microcrystalline silicon layer 334 may be formed to a thickness between about 10,000 Å and about 30,000 Å, and the n-type amorphous silicon layer 336 may be formed to a thickness between about 100 Å and about 500 Å. The back contact layer 350 may include, but is not limited to, a material selected from Al, Ag, Ti, Cr, Au, Cu, Pt, alloys thereof, and combinations thereof.

FIG. 3C is a plan view that schematically illustrates an example of the rear surface of four solar cells 300 (e.g., smaller solar cells 300A-300D) that have been formed from a single substrate 302, as may be produced in the production line 200. The smaller solar cells 300A-300D are formed by removing sections (e.g., reference numeral 386) of the deposited layers (e.g., reference numerals 310-350) on the substrate 302, sectioning the substrate 302, and completing the formation of the smaller solar cells 300A-300D. Although four smaller solar cells 300A-300D are shown, this is not intended to limit the scope of the invention as the invention described herein is equally applicable to any number of solar cells 300 formed from a single large substrate 302. For instance, the production line 200 may be capable of producing a single 5.7 m² solar cell 300, two 2.8 m² smaller solar cells 300, or four 1.4 m² smaller solar cells 300 from a single 5.7 m² substrate 302 via process sequence 100. In addition, the production line 200 may be capable of forming one or more solar cells 300 having any number of custom sizes and/or shapes. For instance, FIG. 3D depicts two oval shaped solar cells 300E and 300F formed from a single substrate 302, produced in the production line 200 according to the process sequence 100.

FIG. 3E is a side cross-sectional view of a portion of one of the solar cells 300A illustrated in FIG. 3C (see section A-A). While FIG. 3E illustrates the cross-section of a single junction cell similar to the configuration described in FIG. 3A, this is not intended to limit the scope of the invention described herein.

As shown in FIGS. 3C-3E, each of the solar cells 300A-300F may contain a portion of the substrate 302, portions of the deposited solar cell device elements (e.g., reference numerals 310-350), one or more internal electrical connections (e.g., side buss 355, cross-buss 356), a portion of the layer of bonding material 360, a portion of the back glass substrate 361, and a junction box 370. The junction box 370 may include two connection points 371, 372 that are electrically connected to portions of the smaller solar cell 300A-300D through the side buss 355 and the cross-buss 356, which are in electrical communication with the back contact layer 350 and active regions (i.e., reference numeral 320) of each of the smaller solar cells 300A-300F. Although the junction boxes 370 are depicted as being mounted in a central location to the cross-buss 356 of each of the solar cells 300A-300F, this is not intended to limit the scope of the invention. For instance, a junction box 370 may alternatively be positioned at one end of each side buss 355 of each solar cell 300A-300F rather than connected to the cross-buss 356.

To avoid confusion relating to the actions specifically performed on the substrates 302 in the discussion below, a substrate 302 having one or more of the deposited layers (e.g., reference numerals 310-350) and/or one or more internal electrical connections (e.g., side buss 355, cross-buss 356) disposed thereon is generally referred to as a device substrate 303. Similarly, a device substrate 303 that has been bonded to a back glass substrate 361 using a layer of bonding material 360 is referred to as a composite solar cell structure 304. In general, configurations in which a single solar cell is formed across the entire substrate 302 are specifically noted. Otherwise, it is intended that the phrase “solar cell 300” generally signifies one of the one or more, smaller solar cells (e.g., reference numerals 300A-300D in FIG. 3C or 300E-300F in FIG. 3D) formed from portions of the larger substrate 302 using the steps described below.

FIG. 3F is a schematic cross-section of a solar cell 300 illustrating various scribed regions used to form the individual cells 382A-382B within the solar cell 300. In one example, as shown in FIG. 3C, there are five individual cells 382 formed in the smaller solar cell 300A, excluding the end regions 383. As illustrated in FIG. 3F, the solar cell 300 includes a transparent substrate 302, a first TCO layer 310, a first p-i-n junction 320, and a back contact layer 350. Four scribing steps, such as laser scribing steps, may be performed to produce trenches 381A, 381B, 381C, and 381D which are generally required to form a high efficiency solar cell device. Although formed together on the substrate 302, the individual cells 382A and 382B are isolated from each other by the insulating trench 381C formed in the back contact layer 350 and the first p-i-n junction 320. In addition, the trench 381 B is formed in the first p-i-n junction 320 so that the back contact layer 350 is in electrical contact with the first TCO layer 310. In one embodiment, the insulating trench 381A is formed by the laser scribe removal of a portion of the first TCO layer 310 prior to the deposition of the first p-i-n junction 320 and the back contact layer 350. Similarly, in one embodiment, the trench 381B is formed in the first p-i-n junction 320 by the laser scribe removal of a portion of the first p-i-n junction 320 prior to the deposition of the back contact layer 350. In addition, the trench 381D is formed through the back contact layer 350, the first p-i-n junction 320, and the first TCO layer 310 both for edge isolation and separation of individual smaller solar cells 300A-300F on the substrate 302.

For BIPV applications, additional trenches 381E are scribed into the back contact layer 350 and first p-i-n junction 320 to provide semi-transparency to the solar cell 300 when viewed from the front surface or the rear surface of the solar cell 300. In one embodiment, the additional trenches 381E are a series of non-overlapping “spots” as shown in FIG. 3C. In this embodiment, the “spots” may be any of a number of shapes (e.g., circular, oval, square, rectangular) to achieve a transparent appearance. The “spots” may also be any of a number of sizes, just as long as they do not overlap with one another. In another embodiment, the additional trenches 381E are a series of trenches scribed substantially perpendicular to the trenches 381C, as shown in FIG. 3D. In this embodiment, the trenches 381E may have any number of lengths and widths as long as they do not overlap with each other or with an adjacent trench 381C or 381D. These configurations of the trenches 381E, as well as a number of other configurations of the trenches 381E, provide semi-transparency through the solar cell 300 without interrupting current flow in the back contact layer 350. While a single junction type solar cell is illustrated in FIG. 3F this configuration is not intended to limit the scope of the invention described herein.

### General Solar Cell Formation Process Sequence

Referring to FIGS. 1 and 2, the process sequence 100 generally starts at step 102 in which a substrate 302 is loaded into the loading module 202 found in the solar cell production line 200. In one embodiment, the substrates 302 are received in a “raw” state where the edges, overall size, and/or cleanliness of the substrates 302 are not well controlled. Receiving “raw” substrates 302 reduces the cost to prepare and store substrates 302 prior to forming a solar cell device and thus reduces the solar cell device cost, facilities costs, and production costs of the finally formed solar cell device. However, typically, it is advantageous to receive “raw” substrates 302 that have a transparent conducting oxide (TCO) layer (e.g., first TCO layer 310) already deposited on a surface of the substrate 302 before it is received into the system in step 102. If a conductive layer, such as TCO layer, is not deposited on the surface of the “raw” substrates then a front contact deposition step (step 107), which is discussed below, needs to be performed on a surface of the substrate 302.

In one embodiment, the substrates 302 or 303 are loaded into the solar cell production line 200 in a sequential fashion, and thus do not use a cassette or batch style substrate loading system. A cassette style and/or batch loading type system that requires the substrates to be un-loaded from the cassette, processed, and then returned to the cassette before moving to the next step in the process sequence can be time consuming and decrease the solar cell production line throughput. The use of batch processing does not facilitate certain embodiments of the present invention, such as fabricating multiple solar cell devices from a single substrate. Additionally, the use of a batch style process sequence generally prevents the use of an asynchronous flow of substrates through the production line, which is believed to provide improved substrate throughput during steady state processing and when one or more modules are brought down for maintenance or due to a fault condition. Generally, batch or cassette based schemes are not able to achieve the throughput of the production line described herein during normal operation, or more particularly, when one or more processing modules are brought down for maintenance, since the queuing and loading of substrates can require a significant amount of overhead time.

In step 104, the surfaces of the substrate 302 are prepared to prevent yield issues later on in the process. In one embodiment of step 104, the substrate is inserted into a front end seaming module 204 that is used to prepare the edges of the substrate 302 or 303 to reduce the likelihood of damage, such as chipping or particle generation from occurring during the subsequent processes. Damage to the substrate 302 or 303 can affect device yield and the cost to produce a usable solar cell device. In one embodiment, the front end seaming module 204 is used to round or bevel the edges of the substrate 302 or 303. In one embodiment, a diamond impregnated belt or disc is used to grind the material from the edges of the substrate 302 or 303. In another embodiment, a grinding wheel, grit blasting, or laser ablation technique is used to remove the material from the edges of the substrate 302 or 303.

Next the substrate 302 or 303 is transported, via an automation system 281, to the cleaning module 206, in which step 106, or a substrate cleaning step, is performed on the substrate 302 or 303 to remove any contaminants found on the surface of thereof. Common contaminants may include materials deposited on the substrate 302 or 303 during the substrate forming process (e.g., glass manufacturing process) and/or during shipping or storing of the substrates 302 or 303. Typically, the cleaning module 206 uses wet chemical scrubbing and rinsing steps to remove any undesirable contaminants. In one embodiment, the automation system comprises of rollers, belts, and other conveyor components controlled by the system controller 290.

Referring to FIGS. 1 and 2, in one embodiment, prior to performing step 108 the substrates 302 are transported to a front end processing module (not illustrated in FIG. 2) in which a front contact formation process, or step 107, is performed on the substrate 302. In one embodiment, the front end processing module is similar to the processing module 218 discussed below. In step 107, the one or more substrate front contact formation steps may include one or more preparation, etching, and/or material deposition steps that are used to form front contact regions on a bare solar cell substrate 302. In one embodiment, step 107 generally comprises one or more physical vapor deposition (PVD) steps that are used to form the front contact region on a surface of the substrate 302. In one embodiment, the front contact region includes the transparent conducting oxide (TCO) layer 310 that may contain a metal element selected from zinc (Zn), aluminum (Al), indium (In), and tin (Sn). In one example, a zinc oxide (ZnO) is used to form at least a portion of the front contact layer. In one embodiment, the front end processing module is an ATON™ PVD 5.7 tool available from Applied Materials in Santa Clara, Calif. in which one or more processing steps are performed to deposit the front contact formation steps. In another embodiment, one or more chemical vapor deposition (CVD) steps are used to form the front contact region on a surface of the substrate 302.

Next the device substrate 303 is transported, via the automation system 281, to the scribe module 208 in which step 108, or a front contact isolation step, is performed on the device substrate 303 to electrically isolate different regions of the device substrate 303 surface from each other. In step 108, material is removed from the device substrate 303 surface by use of a material removal step, such as a laser ablation process. The success criteria for step 108 are to achieve good cell-to-cell and cell-to-edge isolation while minimizing the scribe area. In one embodiment, a Nd:vanadate (Nd:YVO₄) laser source is used ablate material from the device substrate 303 surface to form lines that electrically isolate one region of the device substrate 303 from the next. In one embodiment, the laser scribe process performed during step 108 uses a 1064 nm wavelength pulsed laser to pattern the material disposed on the substrate 302 to isolate each of the individual cells (e.g., individual cells 382A and 382B) that make up the solar cell 300. In one embodiment, a 5.7 m² substrate laser scribe module available from Applied Materials, Inc. of Santa Clara, Calif. is used to provide simple reliable optics and substrate motion for accurate electrical isolation of regions of the device substrate 303 surface. In another embodiment, a water jet cutting tool or diamond scribe is used to isolate the various regions on the surface of the device substrate 303.

Next, the device substrate 303 is transported, via the automation system 281, to the cleaning module 210 in which step 110, or a pre-deposition substrate cleaning step, is performed on the device substrate 303 to remove any contaminants found on the surface of the device substrate 303 after performing the front contact isolation step (step 108). Typically, the cleaning module 210 uses wet chemical scrubbing and rinsing steps to remove any undesirable contaminants found on the device substrate 303 surface after performing the cell isolation step. In one embodiment, a cleaning process, similar to the processes described in step 106 above, is performed on the device substrate 303 to remove any contaminants on the surface(s) of the device substrate 303.

Next, the device substrate 303 is transported, via the automation system 281, to the processing module 212 in which step 112, which comprises one or more photoabsorber deposition steps, is performed on the device substrate 303. In step 112, the one or more photoabsorber deposition steps may include one or more preparation, etching, and/or material deposition steps that are used to form various regions of the solar cell device. Step 112 generally comprises a series of sub-processing steps that are used to form one or more p-i-n junctions, such as the first p-i-n junction 320 and the second p-i-n junction 330. In one embodiment, the one or more p-i-n junctions comprise amorphous silicon and/or microcrystalline silicon materials.

In general, the one or more processing steps are performed in one or more cluster tools (e.g., cluster tools 212A-212D) found in the processing module 212 to form one or more layers on the device substrate 303. In one embodiment, in cases where the solar cell device is formed to include multiple junctions, such as the tandem junction solar cell 300 illustrated in FIG. 3B, the cluster tool 212A in the processing module 212 is adapted to form the first p-i-n junction 320 and cluster tools 212B-212D are configured to form the second p-i-n junction 330.

Next, the device substrate 303 is transported, via the automation system 281, to the scribe module 214 in which an interconnect formation step, or step 114, is performed on the device substrate 303 to electrically isolate various regions of the device substrate 303 surface from each other. In step 114, material is removed from the device substrate 303 surface by use of a material removal step, such as a laser ablation process. In one embodiment, an Nd:vanadate (Nd:YVO₄) laser source is used ablate material from the substrate surface to form lines that electrically isolate one individual cell from the next. In one embodiment, a 5.7 m² substrate laser scribe module available from Applied Materials, Inc. is used to perform the accurate scribing process. In one embodiment, the laser scribe process performed during step 114 uses a 532 nm wavelength pulsed laser to pattern the material disposed on the device substrate 303 to isolate the individual cells that make up the solar cell 300. As shown in FIG. 3F, in one embodiment, the trench 381B is formed in the first p-i-n junction 320 layers by use of a laser scribing process during step 114. In another embodiment, a water jet cutting tool or diamond scribe is used to isolate the various regions on the surface of the device substrate 303.

Next, the device substrate 303 is transported, via the automation system 281, to the processing module 218 in which one or more back contact formation steps, or step 118, are performed on the device substrate 303. In step 118, the one or more back contact formation steps may include one or more preparation, etching, and/or material deposition steps that are used to form the back contact regions of the solar cell device. In one embodiment, step 118 generally comprises one or more PVD steps that are used to form the back contact layer 350 on the surface of the device substrate 303. In one embodiment, the one or more PVD steps are used to form a back contact region that contains a metal layer selected from zinc (Zn), tin (Sn), aluminum (Al), copper (Cu), silver (Ag), nickel (Ni), and vanadium (V). In one example, a zinc oxide (ZnO) or nickel vanadium alloy (NiV) is used to form at least a portion of the back contact layer 350. In one embodiment, the one or more processing steps are performed using an ATON™ PVD 5.7 tool available from Applied Materials in Santa Clara, Calif. In another embodiment, one or more CVD steps are used to form the back contact layer 350 on the surface of the device substrate 303.

Next, the device substrate 303 is transported, via the automation system 281, to the scribe module 220 in which step 120, or a back contact isolation step, is performed on the device substrate 303 to electrically isolate the individual cells disposed on the substrate surface from each other. In step 120, material is removed from the substrate surface by use of a material removal step, such as a laser ablation process. In one embodiment, an Nd:vanadate (Nd:YVO₄) laser source is used ablate material from the device substrate 303 surface to form lines that electrically isolate one individual cell from the next. In one embodiment, a 5.7 m² substrate laser scribe module, available from Applied Materials, Inc., is used to accurately scribe the desired regions of the device substrate 303. In one embodiment, the laser scribe process performed during step 120 uses a 532 nm wavelength pulsed laser to pattern the material disposed on the device substrate 303 to isolate the individual cells that make up the solar cell 300. As shown in FIG. 3F, in one embodiment, the trench 381C is formed in the first p-i-n junction 320 and back contact layer 350 by use of a laser scribing process.

Next, the device substrate 303 is transported, via the automation system 281, to a multifunction laser module 222 in which laser scribing steps 122 are performed on the device substrate 303. In the case of BIPV panel production, a material removal step 122a may be performed on the device substrate 303 to create transparent regions in the device substrate 303 via the formation of trenches 381E, as shown in FIGS. 3C-3F. In step 122a, material is removed from the substrate surface by the use of a material removal step, such as a laser ablation process. In one embodiment, an Nd:vanadate (Nd:YVO₄) laser source is used to ablate material from the device substrate 303 surface to form transparent regions, such as trenches 381E in FIGS. 3C-3F. In one embodiment, the laser scribe process performed during step 122a uses a 532 nm wavelength pulsed laser to pattern the material disposed on the device substrate 303 to provide semi-transparency. As shown in FIG. 3E, in one embodiment, the trench 381D is formed in the first p-i-n junction 320 and back contact layer 350 by use of a laser scribing process.

Next, device isolation (or edge delete) steps 122b may be performed on the device substrate 303 to separate regions of the deposited layers to form one or more solar cells 300 (e.g., reference numerals 300A-330F) on the substrate 302, as shown in FIGS. 3C-3E. In step 122b, material is removed from the surface of the substrate 302 by use of a material removal step, such as a laser ablation process. As shown in FIGS. 3C-3F, the material removal device is configured to remove material from edge region 385 and, if necessary, sectioning regions 386 to form the one or more solar cells 300A-300F. The sectioning regions 386 are configured to electrically and physically isolate two or more formed solar cells 300 from each other. After processing, the edge region 385 and sectioning regions 386 are generally free of the materials deposited on the surface of the substrate 302 (e.g., layers 310-350) to form isolated solar cells 300 and allow the bonding material 360 to form a bond to the surface of the substrate 302 in a subsequent processing step (step 132). In one embodiment, an Nd:vanadate (Nd:YVO₄) or Nd:YAG laser source is used to ablate material from the substrate 302 surface to form the edge regions 385 and sectioning regions 386, if needed. In one embodiment, the laser ablation process performed during step 122b uses a 1064 nm wavelength pulsed laser to pattern the material disposed on the substrate 302 to isolate the edges of the one or more solar cells 300. As shown in FIG. 3F, in one embodiment, the trench 381D is formed through the front TCO layer 310, the first p-i-n junction 320, and the back contact layer 350 by use of a laser ablation process.

Next, sectioning step(s) 122c may be performed on the device substrate 303 to form one or more solar cells 300 of a desired size and shape (e.g., solar cells 300A-300F in FIGS. 3C and 3D). In one embodiment, the device substrate 303 is sectioned along reference lines X-X and Y-Y, as shown in FIG. 3C. In one embodiment, the reference lines X-X and Y-Y are positioned at substantially the mid point of the sectioning region(s) 386. In another embodiment, the device substrate 303 is sectioned according to other desired sizes and shapes (e.g., FIG. 3D). In one embodiment, a laser cutting device is used to accurately cut and section the device substrate 303 to form solar cell devices that are a desired shape and size. In one embodiment a diamond scribe is used to initiate a crack in the substrate 302 and a high power CO₂ laser is used to propagate the crack until the device substrate is sectioned. In one embodiment, a carbon dioxide laser that can emit a continuous wave of radiation with the principal wavelength bands centering around about 9.4 μm and about 10.6 μm is used. In some embodiments of the present invention, sectioning step(s) 122c are not performed on the device substrate 303 within the multifunction laser module 222, rather an optional sectioning step 140 is performed on the composite structure 304 in a sectioning module 240 as subsequently described.

Although the process steps 122a, 122b, and 122c are provided above in sequence, embodiments of the present invention are not so limited. In certain embodiments, one or more of the process steps 122a, 122b, and 122c may be omitted or performed out of the above presented sequence. In certain embodiments, one or more of the process steps 122a, 122b, and 122c may be performed substantially simultaneously.

In one embodiment, the solar cell production line 200 is adapted to accept (step 102) and process substrate 302 or device substrates 303 that are 5.7 m² or larger. In one embodiment, these large area substrates 302 are processed and then isolated and sectioned into one or more device substrates 303 of a desired shape and size during steps 122b and 122c. Currently amorphous silicon (a-Si) thin film factories must have one product line for each different size solar cell device and are unable to produce custom shapes and sizes. In the present invention, the production line 200 is able to manufacture different solar cell device sizes and shapes with minimal or no conversion time.

This flexibility in output with a single input is unique in the solar thin film industry and offers significant savings in capital expenditure and reduction in processing complexity. The material cost for the input glass is also lower since solar cell device manufacturers can purchase a larger quantity of a single glass size to produce the various sized and shaped solar cell devices. A more detailed description of an exemplary multifunction laser module 222 is presented below in the section entitled, “Multifunction Laser Module and Processes.”

Next, the device substrate 303 is transported, via the automation system 281, to the quality assurance module 224 in which step 124, or quality assurance and/or shunt removal steps, are performed on regions of the device substrate 303 to assure that the devices formed on the substrate surface meet a desired quality standard and, in some cases, to correct defects in the formed device. In one embodiment, the analyzed and processed regions of the device substrate 303 include each of the individual cells (e.g., individual cells 382A-382B in FIG. 3F). In step 124, a probing device is used to measure the quality and material properties of the formed solar cell device by use of one or more substrate contacting probes. In one embodiment, the quality assurance module 224 projects a low level of light at the p-i-n junctions of the solar cells and uses the one more probes to measure the output of the cells to determine the electrical characteristics of the formed solar cell devices.

If the module detects a defect in the formed device, it can take corrective actions to correct the defects in the formed smaller solar cells 300 on the device substrate 303. In one embodiment, if a short or other similar defect is found, a reverse bias may be applied between regions on the substrate surface to control and or correct one or more of the defectively formed regions of the solar cell device. During the correction process the reverse bias generally delivers a voltage high enough to cause the defects in the solar cells to be corrected. In one example, if a short is found between supposedly isolated regions of the device substrate 303 the magnitude of the reverse bias may be raised to a level that causes the conductive elements in areas between the isolated regions to change phase, decompose, or become altered in some way to eliminate or reduce the magnitude of the electrical short.

In one embodiment of the process sequence 100, the quality assurance module 224 and factory automation system are used together to resolve quality issues found in a formed device substrate 303 during the quality assurance testing. In one case, a device substrate 303 may be sent back upstream in the processing sequence to allow one or more of the fabrication steps to be re-performed on the device substrate 303 (e.g., back contact isolation step (step 120)) to correct one or more quality issues with the processed device substrate 303.

Next, the device substrate 303 is transported, via the automation system 281, to a cleaning module 226 in which step 126, or a pre-lamination cleaning step, is performed on the device substrate 303 to remove any contaminants found on the surface of the multiple smaller solar cells 300 formed on the device substrate 303. Typically, the cleaning module 226 uses wet chemical scrubbing and rinsing steps to remove any undesirable contaminants found on the substrate surface. In one embodiment, a cleaning process similar to the processes described in step 106 is performed on the substrate 303 to remove any contaminants on the surface(s) of the substrate 303, such as the edge region 385, sectioning regions 386, back contact layer 350, trenches 381C and 381D, and front surface and edges of the substrate 302. In one embodiment, optical inspection or electrical conductivity tests are performed on various portions of the edge region 385 or sectioning regions 386 after step 126 to assure that all of the desired material has been removed. In one embodiment of the processing sequence 100, step 126 is performed on the device substrate 303 prior to performing step 124.

Next, the substrate 303 is transported, via the automation system 281, to a bonding wire attach module 228 in which step 128, or a bonding wire attach step, is performed on the device substrate 303. Step 128 is used to attach the various wires/leads required to connect the various external electrical components to the formed smaller solar cell devices formed on the substrate 302. Typically, the bonding wire attach module 228 is an automated wire bonding tool that is used to reliably and quickly form the numerous interconnects that are often required to form the solar cells 300 formed in the production line 200. In one embodiment, the bonding wire attach module 228 is used to form the side-buss 355 (FIG. 3C) and cross-buss 356 on the formed back contact region (step 118) of each of the smaller solar cells 300. In this configuration the side-buss 355 may be a conductive material that can be affixed, bonded, and/or fused to the back contact layer 350 found in the back contact region to form a good electrical contact.

In one embodiment, the side-buss 355 and cross-buss 356 each comprise a metal strip, such as copper tape, a nickel coated silver ribbon, a silver coated nickel ribbon, a tin coated copper ribbon, a nickel coated copper ribbon, or other conductive material that can carry the current delivered by each solar cell and be reliably bonded to the metal layer in the back contact region. In one embodiment, the metal strip is between about 2 mm and about 10 mm wide and between about 1 mm and about 3 mm thick. The cross-buss 356, which is electrically connected to the side-buss 355 at the junctions, can be electrically isolated from the back contact layer 350 of each of the smaller solar cells 300 by use of an insulating material 357, such as an insulating tape, as shown in FIG. 3C. The ends of each of the cross-busses 356 generally have one or more leads that are used to connect the side-buss 355 and the cross-buss 356 to the electrical connections found in a junction box 370, which is used to connect the formed solar cell to the other external electrical components.

In step 130, a bonding material 360 (FIG. 3E) and “back glass” substrate 361 are prepared for delivery into the solar cell formation process (i.e., process sequence 100). The preparation process is generally performed in the glass lay-up module 230, which generally comprises a material preparation module 230A, a glass loading module 230B, and a glass cleaning module 230C. The back glass substrate 361 is bonded onto the device substrate 303 formed in steps 102-128 above by use of a laminating process (step 132 discussed below). In general, step 130 requires the preparation of a polymeric material that is to be placed between the back glass substrate 361 and the deposited layers on the device substrate 303 having the edge region 385 and sectioning regions 386 formed thereon to form a hermetic seal between the back glass 361 and portions of the exposed substrate 302 surface during a subsequent step (step 132). The formed hermetic seal prevents the environment from attacking the one or more solar cells 300 during their useful lives.

Referring to FIGS. 1 and 2, step 130 generally comprises a series of sub-steps. First, a bonding material 360 is prepared to the appropriate size and shape in the material preparation module 230A. The bonding material 360 is then placed over the device substrate 303. Next, the appropriately sized and shaped back glass substrate 361 is loaded into the glass loading module 230B and is washed by use of the cleaning module 230C. Finally, the back glass substrate 361 is placed over the bonding material 360 and the device substrate 303.

In one embodiment, the material preparation module 230A is adapted to receive the bonding material 360 in a sheet form and perform one or more cutting operations to provide a bonding material, such as Polyvinyl Butyral (PVB) or Ethylene Vinyl Acetate (EVA) that is sized and shaped to cover the surface of the substrate 302 on which the deposited layers (e.g., reference numerals 310-350) are disposed. In one embodiment, PVB may be used to advantage due to its UV stability, moisture resistance, thermal cycling, good US fire rating, compliance with International Building Code, low cost, and reworkable thermo-plastic properties.

In one part of step 130, the bonding material 360 is transported and positioned over the back contact layer 350, the side-buss 355 (FIG. 3C), and the cross-buss 356 (FIG. 3C) elements of the device substrate 303 using an automated robotic device. The device substrate 303 and bonding material 360 are then positioned to receive a back glass substrate 361, which can be placed thereon by use of the same automated robotic device used to position the bonding material 360, or a second automated robotic device.

In one embodiment, prior to positioning the back glass substrate 361 over the bonding material 360, one or more preparation steps are performed on the back glass substrate 361 to assure that subsequent sealing processes and final solar product are desirably formed. In one case, the back glass substrate 361 is received in a “raw” state where the edges, overall size, and/or cleanliness of the substrate 361 are not well controlled. Receiving “raw” substrates reduces the cost to prepare and store substrates prior to forming a solar device and thus reduces the solar cell device cost, facilities costs, and production costs of the finally formed solar cell device. In one embodiment of step 130, the back glass substrate 361 is cut to the desired size and shape, and the surfaces and edges are prepared in a seaming module (e.g., front end seaming module 204) prior to performing the back glass substrate cleaning step. In the next sub-step of step 132, the back glass substrate 361 is transported to the glass cleaning module 230C in which a substrate cleaning step is performed on the substrate 361 to remove any contaminants on the surface of the substrate 361. Common contaminants may include materials deposited on the substrate 361 during the substrate forming process (e.g., glass manufacturing process) and/or during shipping of the substrates 361. Typically, the glass cleaning module 230C uses wet chemical scrubbing and rinsing steps to remove any undesirable contaminants as discussed above. The prepared back glass substrate 361 is then positioned over the bonding material 360 and the device substrate 303 by use of an automated robotic device.

Next, the device substrate 303, the back glass substrate 361, and the bonding material 360 are transported, via the automation system 281, to the bonding module 232 in which lamination steps, or step 132, are performed to bond the back glass substrate 361 to the device substrate 303 formed in steps 102-130 discussed above. In step 132, the bonding material 360, such as Polyvinyl Butyral (PVB) or Ethylene Vinyl Acetate (EVA), is sandwiched between the back glass substrate 361 and the device substrate 303. Heat and pressure are applied to the structure to form a bonded and sealed device using various heating elements and other devices found in the bonding module 232.

The device substrate 303, the back glass substrate 361, and bonding material 360 thus form a composite solar cell structure 304 (FIG. 3E) that at least partially encapsulates the active regions of the solar cell device. In one embodiment, at least one hole, formed in the back glass substrate 361, remains at least partially uncovered by the bonding material 360 for each of the smaller solar cells 300 formed on the substrate 302. This allows portions of the cross-buss 356 or the side buss 355 to remain exposed so that electrical connections can be made to these regions of the composite solar cell structure 304 in future steps (i.e., step 138).

Next, the composite solar cell structure 304 is transported, via the automation system 281, to the autoclave module 234 in which step 134, or autoclave steps are performed on the composite solar cell structure 304 to remove trapped gasses in the bonded structure and assure that a good bond is formed. In step 134, a composite solar cell structure 304 is inserted into the processing region of the autoclave module 234, where heat and high pressure gases are delivered to reduce the amount of trapped gas and improve the properties of the bond between the device substrate 303, back glass substrate 361, and the bonding material 360. The processes performed in the autoclave module 234 are also useful to assure that the stress in the glass and bonding layer (e.g., PVB layer) are controlled to prevent future failures of the hermetic seal or failure of the glass due to the stress induced during the bonding/lamination processes. In one embodiment, it may be desirable to heat the device substrate 303, back glass substrate 361, and bonding material 360 to a temperature that causes stress relaxation in one or more of the components in the composite solar cell structure 304.

Next, the composite solar cell structure 304 is transported, via the automation system 281, to the junction box attachment module 236 in which junction box attachment steps 136 are performed on the composite solar cell structure 304. The junction box attachment module 236, used during step 136, is used to install a junction box 370 (FIG. 3C) on each solar cell 300 formed on the substrate 302. The installed junction box 370 acts as an interface between the external electrical components that will connect to each formed solar cell, such as other solar cells or a power grid, and the internal electrical connections points, such as the leads, formed during step 128. In one embodiment, the junction box 370 contains one or more connection points 371, 372 so that each formed solar cell can be easily and systematically connected to other external devices to deliver the generated electrical power. In one embodiment, a junction box 370 is attached to one end of each of the side busses 355 (not shown) instead of to a central portion of the cross-buss 356 as shown in FIGS. 3C and 3D.

Next, the composite solar cell structure 304 is transported, via the automation system 281, to the device testing module 238 in which device screening and analysis steps 138 are performed on the composite solar cell structure 304 to assure that the device(s) formed in the composite solar cell structure 304 meet desired quality standards. In one embodiment, the device testing module 238 is a solar simulator module that is used to qualify and test the output of the one or more formed smaller solar cells 300. In step 138, a light emitting source and probing device are used to measure the output of the one or more formed solar cells 300 by use of one or more automated components that are adapted to make electrical contact with terminals in the junction box 370. If the module detects a defect in the formed device, it can take corrective actions or the composite solar cell structure 304 can be scrapped.

Next, the composite solar cell structure 304 is optionally transported to the sectioning module 240 in which a sectioning step 140 is used to section the composite solar cell structure 304 into a plurality of smaller solar cells 300 to form a plurality of smaller solar cell devices. In one embodiment, the composite solar cell structure 304 is sectioned along reference lines X-X and Y-Y, as shown in FIG. 3C. In one embodiment, the reference lines X-X and Y-Y are positioned at substantially the mid point of the sectioning region(s) 386. In one example, a composite solar cell structure 304 having an edge region 385 that is 10 mm wide and section region(s) 386 that are 20 mm wide allows each of the plurality of the formed smaller solar cells 300 to have edge regions 385 that are 10 mm wide, which surround the active portion of the solar cell 300. In one embodiment, the composite solar cell structure 304 is sectioned into one or more solar cells 300 of a desired, custom size and shape (e.g., FIG. 3D). In one embodiment of step 140, the composite solar cell structure 304 is inserted into sectioning module 240 that uses a CNC glass cutting tool to accurately cut and section the composite solar cell structure 304 to form one or more solar cell devices that are a desired size and shape. In one embodiment, the composite solar cell structure 304 is inserted the sectioning module 240 that uses a laser cutting device to accurately cut and section the composite solar cell structure 304 to form one or more solar cell devices that are a desired size and shape. In one embodiment, the composite solar cell structure 304 is inserted into the sectioning module 240 that uses a glass scoring tool to accurately score the surface of the device substrate 302 and the surface of the back glass substrate 361. The composite solar cell structure 304 is then broken or laser cut along the scored lines to produce the desired size and number of fully formed and tested solar cell devices. In one embodiment, after performing the cut and/or break operations, the bonding material 360 disposed between the glass substrate 302 and the back glass substrate 361 is cut to assure separation of the one or more solar cell composite structures 304. In one embodiment, the process of cutting the bonding material 360 is performed in the sectioning module 240 by used of a cutting device, such as a knife, saw, cutting wheel, laser, or other similar device. In one embodiment, an additional step of cutting the bonding material 360 is performed after all of the cut and/or breaking operations are performed.

In one embodiment, the solar cell production line 200 is adapted to accept (step 102) and process substrate 302 or device substrates 303 that are 5.7 m² or larger. In one embodiment, these large area substrates 302 are fully processed and then sectioned into four 1.4 m² device substrates 303 during step 140. In one embodiment, the system is designed to process large device substrates 303 (e.g., TCO coated 2200 mm×2600 mm×3 mm glass) and produce various sized and shaped solar cell devices without additional equipment or processing steps. Currently amorphous silicon (a-Si) thin film factories must have one product line for each different size solar cell device. In the present invention, the production line 200 is able to manufacture different solar cell device sizes and shapes with minimal or no conversion time. In one aspect of the invention, the manufacturing line is able to provide a high solar cell device throughput, which is typically measured in Mega-Watts per year, by forming solar cell devices on a single large substrate and then sectioning the substrate to form solar cells of a more preferable size and shape.

This flexibility in output with a single input is unique in the solar thin film industry and offers significant savings in capital expenditure and reduction in processing complexity. The material cost for the input glass is also lower since solar cell device manufacturers can purchase a larger quantity of a single glass size to produce the various size solar cell devices. A more detailed description of exemplary sectioning modules 240 are presented below in the section entitled, “Sectioning Module and Processes.”

Next, each composite solar cell structure 304 is optionally transported to a back end seaming module 242 in which a seaming step 142 is used to prepare the edges of each composite solar cell structure 304 to reduce the likelihood of damage, such as chipping or crack initiation from the edge of the composite solar cell structure 304. In one embodiment, the back end seaming module 242 is used to round or bevel the edges of each composite solar cell structure 304. In one embodiment, a diamond impregnated belt or disc is used to grind the material from the edges of the composite solar cell structure 304. In another embodiment, a grinding wheel, grit blasting, or laser ablation technique is used to remove the material from the edges of the composite solar cell structure 304. The seaming step 142 is typically not needed if laser cutting of the device substrate 303 or composites structure 304 was performed because far fewer micro-cracks are introduced into the surface or edges of the glass in laser sectioning processes than in traditional mechanical processes.

Next, each composite solar cell structure 304 is transported, via the automation system 281, to the support structure module 244 in which support structure mounting steps 144 are performed on each composite solar cell structure 304 to provide a complete solar cell device that has one or more mounting elements attached to the composite solar cell structure 304 formed using steps 102-142 to a complete solar cell device that can easily be mounted and rapidly installed at a customer's site.

Next, the composite solar cell structure 304 is transported to the unload module 246 in which step 146, or device unload steps are performed to remove the formed smaller solar cells 300 from the solar cell production line 200.

In one embodiment of the solar cell production line 200, one or more regions in the production line are positioned in a clean room environment to reduce or prevent contamination from affecting the solar cell device yield and useable lifetime. In one embodiment, as shown in FIG. 2, a class 10,000 clean room space 250 is placed around the modules used to perform steps 108-118 and steps 128-132.

### Multifunction Laser Module and Processes

The multifunction laser module 222 and processing sequence(s) performed during the laser scribing steps 122 may be used to create transparent regions in the device substrate 303 for BIPV applications (122a), to remove all deposited layers from regions of the device substrate 303 for edge isolation or device separation (122b), and/or to cut or section the device substrate 303 into one or more device substrates 303 of a desired size and shape (122c). In one embodiment, the multifunction laser module 222 receives a 2600 mm×2200 mm device substrate 303, performs laser processes on the device substrate 303, and sections the device substrate 303 into one or more device substrates of a desired size and shape.

In one embodiment, the system controller 290 (FIG. 2) controls all of the functions of the multifunction laser module 222. Thus, the system controller 290 controls the creation of transparent regions on the device substrate 303, the number, size, and shape of edge isolation or device separation regions of the device substrate 303, and the number, size, and shape of device substrates 303 (and ultimately solar cells 300) produced from each substrate 302. Accordingly, the system controller 290 sends commands to all downstream processes in the sequence 100 (FIG. 1) for coordinating both the processes and adjustments to the downstream modules to accommodate and further process sections of the device substrate 303 produced by the multifunction laser module 222.

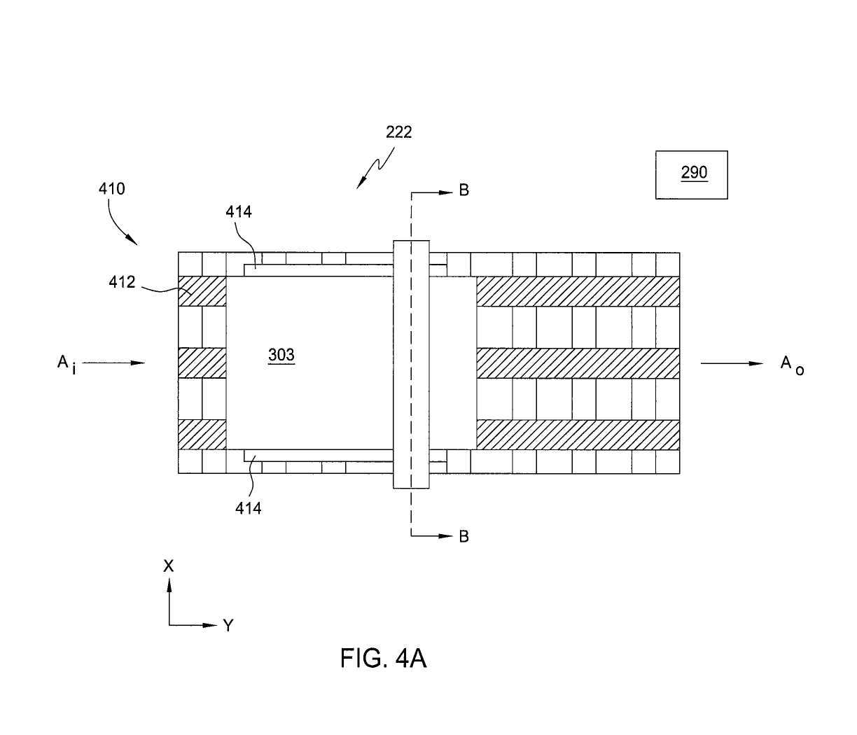

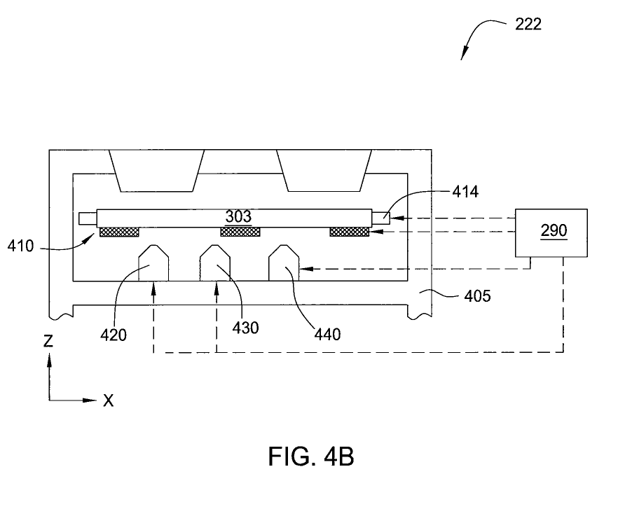

FIG. 4A is a schematic, plan view and FIG. 4B is a schematic, cross-sectional view of a multifunction laser module 222 that may be used to perform one or more of the steps 122 in the process sequence 100 according to one embodiment of the present invention. In general operation, a device substrate 303 is transferred into the laser module 222 following the path Aᵢ. The device substrate 303 is oriented with the surface having material layers (i.e., front contact layer 310, first p-i-n junction 320, back contact layer 350) facing upwardly. The device substrate 303 is then passed over one or more laser devices one or more times while the desired laser operation is performed on the device substrate 303. The device substrate 303 then exits the laser module 222 following path Aₒ.

In one embodiment, the laser module 222 comprises a substrate handling system 410 that includes a support structure 405 that is positioned beneath the device substrate 303 and is adapted to support and retain the various components use to perform laser processes on the device substrate 303. In one embodiment, the substrate handling system 410 includes a conveyor system 412 that has a plurality of conventional, automated conveyor belts for positioning and transferring the device substrate 303 in the laser module 222.

In one embodiment, the substrate handling system 410 further includes one or more substrate grippers 414 for retaining and moving the device substrate 303 during laser processes. The substrate grippers 414 are used to grip the edges of the device substrate 303 and include one or more actuators, such as a linear motor, to translate the device substrate 303 in the Y and −Y directions and/or in the X and −X directions while laser processing is performed on the device substrate 303.

In one embodiment, the multifunction laser module 222 includes one or more BIPV laser devices 420 for creating transparent regions in the device substrate 303. In one embodiment, each BIPV laser device 420 comprises a laser source, various optics, and other support components that are used to control the power, energy, and timing of the delivery of energy used to scribe the desired trenches (e.g., 381E) in the material layers of the device substrate 303 to form a semi-transparent device substrate 303 for use in BIPV applications. In one embodiment, the one or more BIPV laser devices 420 comprise an Nd:vanadate (Nd:YVO₄) laser source is used to ablate material from the device substrate 303 surface to form transparent regions, such as trenches 381E in FIGS. 3C-3F. In one embodiment, the one or more BIPV laser devices 420 comprise a 532 nm wavelength pulsed laser to pattern the material (e.g., the first p-i-n junction 320 and the back contact layer 350) disposed on the device substrate 303 to provide the semi-transparency. Although a 532 nm wavelength is provided, any wavelength capable of removing p-i-n junctions and back contact layers without damaging the front contact layer may be used. In one embodiment, between about 5% and about 50% of the p-i-n junctions and back contact layers are removed. In one embodiment, between about 5% and about 20% of the p-i-n junctions and back contact layers are removed. In one embodiment, the one or more laser devices 420 include galvanometer scanner to move one or more optical components (e.g., mirrors, lenses, fibers) to cause the laser beam to move across at least a portion of the device substrate 303 in the X and −X direction and/or Y and −Y direction during laser ablation processes. Thus, trenches, such as the trenches 381E may be formed in the first p-i-n junction 320 and the back contact layer 350 in desired, custom patterns to create semi-transparent device substrates 303 for further processing into BIPV panels.

In one embodiment, the multifunction laser module 222 includes one or more edge delete laser devices 430 for removing all of the material layers (e.g., front contact layer 310, first p-i-n junction 320, and back contact layer 350) from the device substrate 303 to provide edge isolation regions and/or to separate regions of the deposited layers of the device substrate 303. In one embodiment, each edge delete laser device 430 comprises a laser source, various optics, and other support components that are used to control the power, energy, and timing of the delivery of energy used to remove deposited material from desired regions (e.g., 385, 386) of the device substrate 303 to form physical and electrical isolation regions on the device substrate 303. After processing, the edge region 385 and sectioning regions 386 (FIGS. 3C and 3D) are generally free of the materials deposited on the surface of the substrate 302 (e.g., layers 310-350) to form isolated solar cells 300 and allow the bonding material 360 to form a bond to the surface of the substrate 302 in a subsequent processing step (step 132). In one embodiment, the one or more edge delete laser devices 430 comprise an Nd:vanadate (Nd:YVO₄) or Nd:YAG laser source used to ablate material from the device substrate 303 surface to form the edge regions 385 and sectioning regions 386, if needed. In one embodiment, the laser ablation process performed during step 122b uses a 1064 nm wavelength pulsed laser to pattern the material disposed on the substrate 302 to isolate the edges of the one or more solar cells 300. Although a 1064 nm wavelength is provided, any wavelength capable of removing the front contact layer 310, p-i-n junctions 320/330, and the back contact layer 350 without damaging the substrate 302 may be used. In one embodiment, the one or more edge delete laser devices 430 include galvanometer scanner to move the laser beam to move the laser devices 430 in the X and −X direction and/or Y and −Y direction during laser ablation processes. Therefore, edge isolation regions 385 and/or device separation regions 386 may be formed on the device substrate 303 in desired, custom patterns to form one or more device substrates 303 in desired sizes and shapes for further processing into fully formed solar cell devices.

In one embodiment, the multifunction laser module 222 includes one or more laser cutting devices 440 for cutting the device substrate 303 into one or more device substrates 303 of a desired size and shape. In one embodiment, each laser cutting device 440 comprises a laser source, various optics, and other support components that are used to control the power, energy, and timing of the delivery of energy used to section the device substrate 303 into one or more desired sizes and shapes of device substrates 303 for further processing. In one embodiment, the one or more laser cutting devices 440 includes an optical or mechanical scribe to initiate a crack in the substrate 302 and a high power CO₂ laser source to propagate the crack until the device substrate 303 is cut or sectioned. In one embodiment, the one or more laser cutting devices 440 include a carbon dioxide laser that can emit a continuous wave of radiation with the principal wavelength bands centering around about 9.4 μm and about 10.6 μm. In one embodiment, the one or more laser cutting devices 440 include a galvanometer scanner to adjust the laser beam position during laser processing. Therefore, each device substrate 303 may be cut or sectioned into one or more device substrates 303 having a desired size and shape for further processing into fully formed solar cell devices.

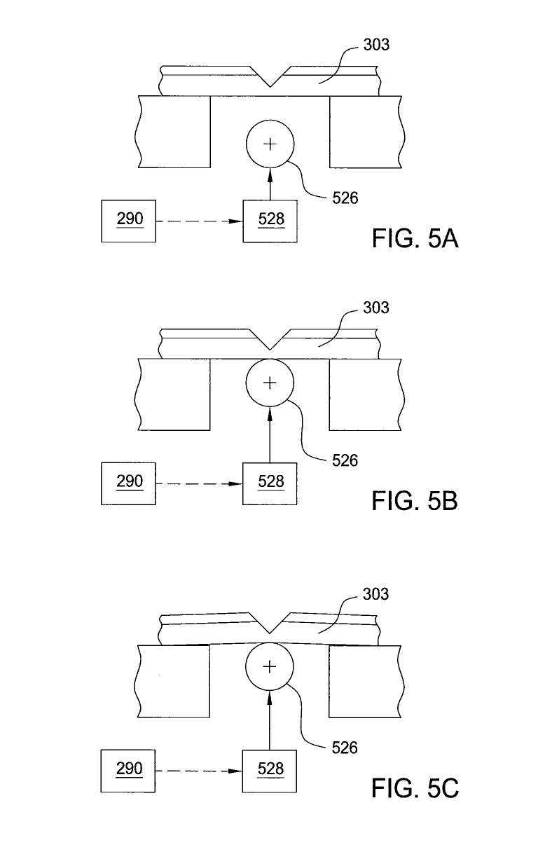

In one embodiment, the one or more laser cutting devices 440 scores the device substrate 303 but does not completely cut through the device substrate 303. FIGS. 5A-5C schematically illustrate a process for breaking the scored device substrate 303 according to one embodiment of the present invention. Referring to FIG. 5A, the scored device substrate 303 is positioned over a roller 526 such that a line scribed along the X-axis is located directly above the roller 526. The roller 526 is then raised and placed in contact with the lower surface of the device substrate 303 as schematically shown in FIG. 5B. As schematically depicted in FIG. 5C, the roller 526 is raised exerting a lifting force on the lower surface of the device substrate 303 along the scribed line and perpendicular to the plane of the device substrate 303 resulting in a clean break along the scribed line.

In one embodiment, the roller 526 is a padded cylindrical roller extending the length of the device substrate 303. The roller 526 is raised by an actuator 528. In one embodiment, the actuator 528 may be an electric, hydraulic, or pneumatic motor. In one embodiment, the actuator 528 may be a hydraulic or pneumatic cylinder. In one embodiment, the actuator 528 is controlled and coordinated by the system controller 290.

### Sectioning Module and Processes

In one embodiment, the sectioning module 240 and processing sequence performed during the sectioning step 140 are used to section a large processed and tested composite solar cell structure 304 into one or more smaller composite solar cell structures 304, each containing a solar cell 300. In one embodiment, the sectioning module 240 receives a 2600 mm×2200 mm composite solar cell structure 304 and sections it into one or more smaller composite solar cell structures 304 having a desired size a shape.

In one embodiment, the system controller 290 (FIG. 2) controls the number, size, and shape of the sections of the composite solar cell structure 304 produced by the sectioning module 240. Accordingly, the system controller 290 sends commands to all downstream processes in the sequence 100 (FIG. 1) for coordinating both the processes and adjustments to the downstream modules to accommodate and further process sections of the composite structure 304 produced by the substrate sectioning module regardless of the size of the sections produced.

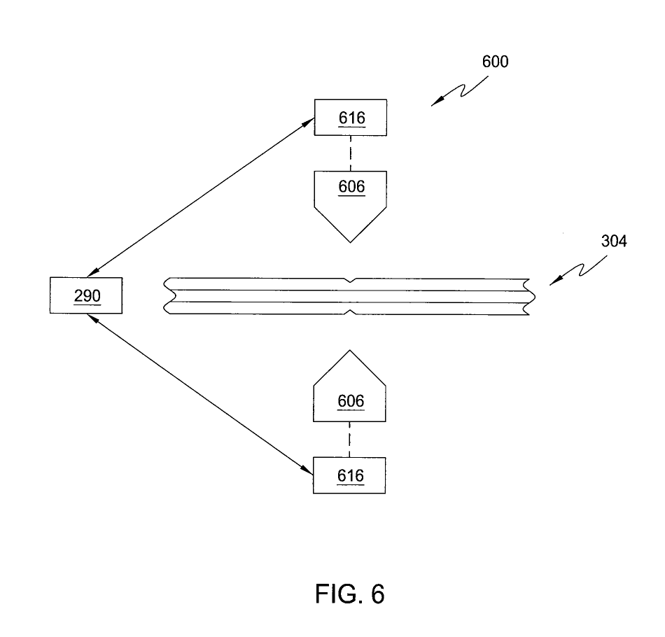

In one embodiment, the composite solar cell structure 304 is sectioned via a laser cutting process. FIG. 6 is a schematic depiction of a laser cutting device 600 sectioning the composite solar cell structure 304 along a scored line produced by a scribe mechanism, such as a diamond scribe. The laser cutting device 600 may comprise a laser source 606 positioned above the composite solar cell structure 304, below the composite solar cell structure 304, or both, and a translation mechanism 616 for moving the laser 606. In one embodiment, the laser 606 is a carbon dioxide laser that can emit a continuous wave of radiation with the principal wavelength bands centering around about 9.4 μm and about 10.6 μm. The translation mechanism 616 may be any suitable linear actuator, such as a linear servo motor or the like. In one embodiment, the translation mechanism 616 is controlled by the controller 290 to control the cutting speed of the laser 606. In one embodiment, the one or more laser cutting device 600 includes a galvanometer scanner, controlled by the system controller 290, to alter the position of the laser beam in the X and −X direction and/or the Y and −Y direction during laser processing. Therefore, each composite structure 304 may be cut or sectioned into one or more composite structures 304 having a desired size and shape for further processing into fully formed solar cell devices.

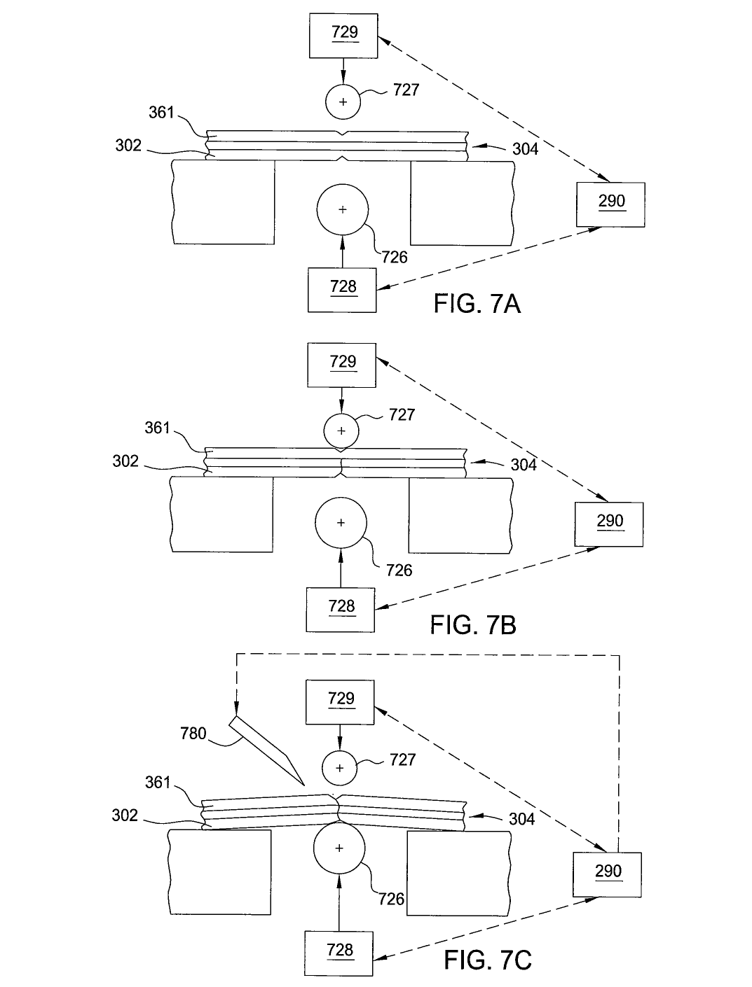

In one embodiment, the laser cutting device 600 scores the composite solar cell structure 304 but does not completely cut through the composite solar cell structure 304. FIGS. 7A-7C schematically illustrate a process for breaking the scored composite solar cell structure 304 according to one embodiment of the present invention. Referring to FIG. 7A, the scored composite solar cell structure 304 is positioned over a roller 726 and under a roller 727 such that a line scored along the X-axis is located directly above the roller 726 and under the roller 727. The roller 727 is then lowered and placed in contact with the upper surface of the back glass substrate 361. As schematically shown in FIG. 7B, the roller 727 is lowered exerting a force on along the scored lines perpendicular to the plane of the composite structure resulting in a clean break in the glass substrate 302 along the scored line. The roller 726 is then raised and placed in contact with the lower surface of the substrate 302. As schematically depicted in FIG. 7C, the roller 726 is raised exerting a lifting force on the lower surface of the composite solar cell structure 304 along the scored line and perpendicular to the plane of the composite solar cell structure 304 resulting in a clean break along the scored line in the back glass substrate 361.

In one embodiment, the rollers 726 and 727 are padded cylindrical rollers extending the length of the composite solar cell structure 304. The roller 726 is raised by an actuator 728, and the roller 727 is lowered by an actuator 729. In one embodiment, the actuator 728 and the actuator 729 may each be an electric, hydraulic, or pneumatic motor. In one embodiment, the actuator 728 and the actuator 729 may each be a hydraulic or pneumatic cylinder. In one embodiment, the actuator 728 and the actuator 729 are each controlled and coordinated by the system controller 290.

In one embodiment, custom or irregularly shaped composite solar cell structure 304 may be desired. In such an embodiment, the actuators 728, 729, and rollers 726, and 727 are configured for adjustment in an automated fashion. The adjustment may involve additional actuators (not shown), controlled by the system controller 290, for adjusting the positioning of the actuators 728, 729 and rollers 726, 727 as needed to form the desired shape and size composite solar cell structure 304.

In one embodiment, after performing the above described cut and/or break operations, it is further desirable to cut the bonding material 360 disposed between the glass substrate 302 and back glass substrate 361 to assure that the sectioned smaller solar cells 300 can be physically separated. In one embodiment, the process of cutting the bonding material 360 is performed in the sectioning module 240 by use of a cutting device 780, such as a knife, saw, cutting wheel, laser, or other similar device. In one embodiment, an additional step of cutting the bonding material 360 is performed after all of the breaking operations are performed.

While the foregoing is directed to embodiments of the present invention, other and further embodiments of the invention may be devised without departing from the basic scope thereof, and the scope thereof is determined by the claims that follow.

1. An apparatus for performing multiple laser functions on a substrate having a plurality of layers formed thereon, comprising:
a substrate handling device configured to support and move the substrate;
a first laser device configured to emit radiation at a first wavelength to remove a portion of at least one of the plurality of layers in a first two dimensional pattern;
a second laser device configured to emit radiation at a second wavelength to propagate a crack in the substrate along a scribed two dimensional pattern, wherein the second wavelength is substantially different than the first wavelength; and
a system controller in communication with the substrate handling device, the first laser device, and the second laser device, wherein the system controller is configured to control the positioning and movement of the substrate, the first laser device, and the second laser device.

2. The apparatus of claim 1, wherein the second laser device comprises a carbon dioxide laser configured to emit a continuous wave of radiation with principal wavelength bands centering around about 9.4 μm and about 10.6 μm.

3. The apparatus of claim 1, wherein the first and second laser devices are configured to operate substantially simultaneously.

4. The apparatus of claim 1, wherein the plurality of layers comprises a front contact layer formed on the substrate, at least one silicon-containing layer formed over the front contact layer, and a back contact layer formed over the at least one silicon-containing layer.

5. The apparatus of claim 4, wherein the first laser device is configured to remove a portion of each of the layers in the first two-dimensional pattern.

6. The apparatus of claim 5, wherein the first laser device comprises a 1064 nm wavelength pulsed laser source.

7. The apparatus of claim 5, further comprising a third laser device configured to emit radiation at a third wavelength to remove a portion of the at least one silicon layer and the back contact layer in a second two-dimensional pattern without removing any of the front contact layer, wherein the third wavelength is substantially different from the first and second wavelengths.

8. The apparatus of claim 7, wherein the third laser source comprises a 532 nm wavelength pulsed laser source.

9. The apparatus of claim 7, wherein the first, second, and third laser sources are configured to operate substantially simultaneously.

10. The apparatus of claim 4, wherein the first laser source is configured to remove a portion of the at least one silicon layer and the back contact layer in a second two-dimensional pattern without removing any of the front contact layer.

11. A method for performing multiple laser functions on a substrate having a plurality of layers formed thereon, comprising:
receiving the substrate onto a substrate handling device;
removing a portion of at least one of the plurality of layers in a first two dimensional pattern by emitting radiation at a first wavelength via a first laser device;
propagating a crack in the substrate along a scribed two dimensional pattern by emitting radiation at a second wavelength via a second laser device, wherein the second wavelength is substantially different than the first wavelength; and
removing the substrate from the substrate handling device.

12. The method of claim 11, wherein removing a portion of the at least one of the plurality of layers and propagating a crack in the substrate are performed substantially simultaneously.

13. The method of claim 11, wherein the plurality of layers comprises a front contact layer formed on the substrate, at least one silicon-containing layer formed over the front contact layer, and a back contact layer formed over the at least one silicon-containing layer.

14. The method of claim 13, wherein removing a portion of at least one of the plurality of layers comprises removing a portion of each of the layers in the first two-dimensional pattern.

15. The method of claim 14, further comprising removing a portion of the at least one silicon-containing layer and the back contact layer in a second two-dimensional pattern without removing any of the front contact layer by emitting radiation at a third wavelength via a third laser device, wherein the third wavelength is substantially different from the first and second wavelengths.

16. The method of claim 15, wherein removing a portion of each of the layers, removing a portion of the at least one silicon-containing layer and the back contact layer, and propagating a crack in the substrate are performed substantially simultaneously.

17. The method of claim 13, wherein removing a portion of at least one of the plurality of layers comprises removing a portion of the at least one silicon-containing layer and the back contact layer without removing any of the front contact layer.

18. A system for fabricating solar cell devices, comprising:
a first scribing module configured to scribe one or more first trenches in a front contact layer of a solar cell substrate;
one or more cluster tools having at least one chamber configured to deposit at least one silicon-containing layer over the front contact layer;
a second scribing module configured to scribe one or more second trenches in the at least one silicon-containing layer;
a deposition module configured to deposit a back contact layer over the at least one silicon-containing layer;
a third scribing module configured to scribe one or more third trenches in the back contact layer;
a multifunction laser module comprising a first laser device and a second laser device, wherein the first laser device is configured emit radiation at a first wavelength to remove a portion of at least the back contact layer and the at least one silicon-containing layer in a first two-dimensional pattern, wherein the second laser device is configured to emit radiation at a second wavelength to propagate a crack in the substrate along a scribed two-dimensional pattern, and wherein the second wavelength is substantially different than the first wavelength; and
a system controller in communication with at least the multifunction laser module, wherein the system controller is configured to control the positioning and movement of the substrate, the first laser device, and the second laser device.

19. The system of claim 18, wherein the first laser device is configured to remove a portion of each of the layers in the first two-dimensional pattern.

20. The system of claim 19, wherein the multifunction laser module further comprises a third laser device configured to emit radiation at a third wavelength to remove a portion of the at least one silicon-containing layer and the back contact layer in a second two-dimensional pattern without removing any of the front contact layer, wherein the third wavelength is substantially different from the first and second wavelengths.
